(19) United States
(12) Patent Application Publication
(10) Pub. No.: US 2008/0023767 A1
(43) Pub. Date: Jan. 31, 2008

(54) HIGH VOLTAGE ELECTROSTATIC DISCHARGE PROTECTION DEVICES AND ELECTROSTATIC DISCHARGE PROTECTION CIRCUITS

(76) Inventor: Steven H. Voldman, South Burlington, VT (US)

Correspondence Address: SCHMEISER, OLSEN & WATTS, 22 CENTURY HILL DRIVE, SUITE 302, LATHAM, NY, 12110, US

(21) Appl. No.: 11/460,286

(22) Filed: Jul. 27, 2006

(51) Int. Cl. H01L 23/62

(52) U.S. Cl. 257/355

(57) ABSTRACT

High-voltage ESD devices and circuits using the high-voltage ESD devices. The high-voltage ESD devices include an N-tub in a P-type substrate; a graded anode having a first P-type region in a second P-type region and located within the N-tub, a concentration of P-type dopant in the first P-type region being greater than a concentration of P-type dopant in the second P-type region; and a graded cathode having a first N-type region in a second N-type region and located within the N-tub, a concentration of N-type dopant in the first N-type region being greater than a concentration of N-type dopant in the second N-type region.

### FIELD OF THE INVENTION

The present invention relates to the field of integrated circuits; more specifically, it relates to high voltage electrostatic discharge protection devices and circuits using the high voltage electrostatic discharge protection devices.

### BACKGROUND OF THE INVENTION

High voltage integrated circuits have operating voltages in excess of 20 volts. Electrostatic discharge (ESD) protection circuits for these high voltage circuits require high voltage ESD devices with junctions that will not breakdown these high operating voltages. Current ESD protection and devices and circuits have been designed to operate at no more than about 14 volts. Therefore, there is a need for devices and circuits that can provide ESD protection for integrated circuits operating at 20 volts and above.

### SUMMARY OF THE INVENTION

A first aspect of the present invention is a device, comprising: an N-tub in a P-type substrate; a graded anode comprising a first P-type region in a second P-type region and located within the N-tub, a concentration of P-type dopant in the first P-type region being greater than a concentration of P-type dopant in the second P-type region; and a graded cathode comprising a first N-type region in a second N-type region and located within the N-tub, a concentration of N-type dopant in the first N-type region being greater than a concentration of N-type dopant in the second N-type region.

A second aspect of the present invention is a circuit, comprising: a diode comprising: a first N-tub in a P-type substrate; a graded anode comprising a first P-type region in a second P-type region and located within the first N-tub, a concentration of P-type dopant in the first P-type region being greater than a concentration of P-type dopant in the second P-type region; and a graded cathode comprising a first N-type region in a second N-type region and located within the first N-tub, a concentration of N-type dopant in the first N-type region being greater than a concentration of N-type dopant in the second N-type region; a transistor comprising: a second N-tub in a P-type substrate; a third P-type region in a fourth P-type region and located within the second N-tub, a concentration of P-type dopant in the third P-type region being greater than a concentration of P-type dopant in the fourth P-type region; a third N-type region in a fourth N-type region and located within the second N-tub, a concentration of N-type dopant in the third N-type region being greater than a concentration of N-type dopant in the fourth N-type region; and an electrically conductive gate and a gate dielectric between the third P-type region and the third N-type region and over the second N-tub; and wherein, the cathode of the diode is connected to a drain of the transistor, an anode of the diode is coupled to the gate of the transistor and coupled to ground, and a source of the transistor is connected to ground.

### BRIEF DESCRIPTION OF DRAWINGS

The features of the invention are set forth in the appended claims. The invention itself, however, will be best understood by reference to the following detailed description of an illustrative embodiment when read in conjunction with the accompanying drawings, wherein:

FIG. 1A is a cross-sectional drawing of a first ESD diode according to an embodiment of the present invention;

FIG. 1B is a cross-sectional drawing the first ESD diode illustrating an alternative isolation scheme according to the embodiment of the present invention;

FIGS. 2A, 2B, 3A and 3B are cross-sectional drawings of third, forth, fifth and sixth ESD diodes according to embodiments of the present invention;

FIG. 4A is a cross-sectional drawing of a first ESD transistor according to an embodiment of the present invention;

FIG. 4B is a cross-sectional drawing of a seventh ESD diode according to an embodiment of the present invention;

FIG. 5A is a cross-sectional drawing of a second ESD transistor according to an embodiment of the present invention;

FIG. 5B is a cross-sectional drawing of an eighth ESD diode according to an embodiment of the present invention;

FIGS. 6A, 6B and 6C are exemplary gated diode ESD string protection devices according to embodiments of the present invention;

FIGS. 7A and 7B are exemplary diode ESD string protection devices according to embodiments of the present invention;

FIGS. 8A and 8B are ESD protection circuits according to embodiments of the present invention; and

FIG. 9 is a control circuit for controlling PDMOS based ESD protection circuits.

### DETAILED DESCRIPTION OF THE INVENTION

For the purposes of the present invention, a high voltage electrostatic discharge (ESD) protection device is a device having the ability to withstand a voltage drop of at least 20 volts across junctions of the device. For the purposes of the present invention, a high voltage ESD protection circuit is a circuit having at least a trigger device and at least a voltage clamp device, both the trigger device and the voltage clamp device being high voltage ESD diodes or transistors having the ability to withstand a voltage drop of at least 20 volts across their junctions.

All the ESD diodes and transistors of the embodiments of the present invention utilize a device structure of a graded anode including a first P-type region formed in a second P-type region and located within an N-tub, a concentration of P-type dopant in the first P-type region being greater than a concentration of P-type dopant in the second P-type region and a first N-type region formed in a second N-type region and located within the N-tub, a concentration of N-type dopant in the first N-type region being greater than a concentration of N-type dopant in the second N-type region. These structures may be considered variants of P and N-type double diffused metal-oxide-silicon field effect transistors (PDMOSFET and NDMOSFET). These will be referred to as PDMOS and NDMOS devices. The PDMOS devices are advantageously used as ESD diodes (or breakdown devices) and the NDMOS devices are advantageously used as ESD transistors.

When the term “dopant species concentration” is used it should be understood that what is meant is the “net dopant concentration species” since a given doped region may contain both N-type and P-type dopant species. N-wells and N-bodies are doped with N-type dopant species and P-wells and P-bodies are doped with P type dopant species. N-type dopant species include arsenic and phosphorous (both may be present in the same doped region) and P-type dopant species include boron.

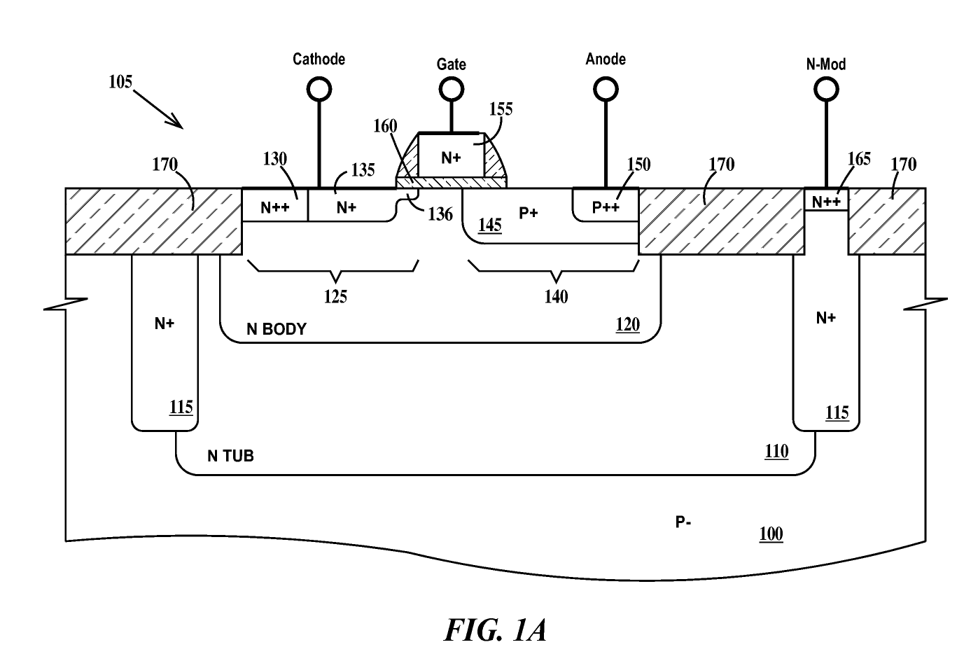

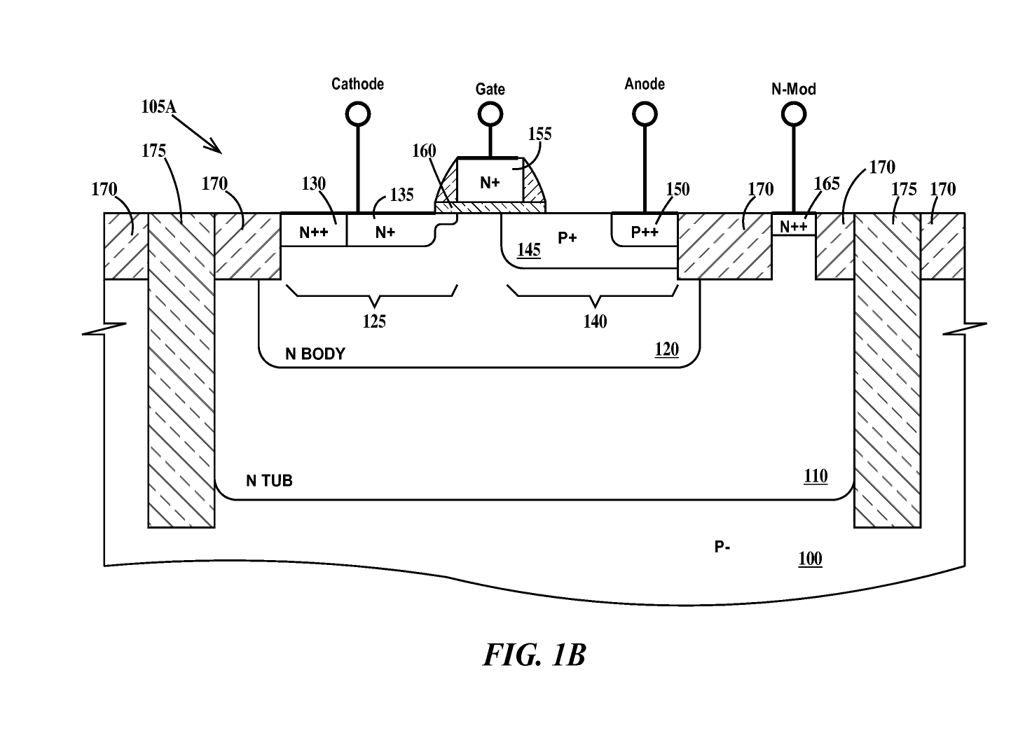

FIG. 1A is a cross-sectional drawing of a first ESD diode according to an embodiment of the present invention. In FIG. 1A, formed in a P-type substrate 100 is an ESD diode 105. ESD diode 105 includes an N-tub (N-type region) 110, isolated from substrate 100 by diffused N-type isolation 115, which surrounds the perimeter of the N-tub. In one example substrate 100 is single-crystal silicon. (In BiCMOS technology, isolation 115 my be the subcollector reach-thru diffusion.) Formed in N-tub 110 is an N-type N-body 120. Formed in N-body 120 is a graded cathode 125 including a N-type region 130 abutting a N-type region 135. Also formed in N-tub 120 is a graded anode 140 including a P-type region 145 and a P-type region 150 formed in P-type region 145.

The concentration of N-type dopant species in N-type region 130 is greater than a concentration of N-type dopant species in N-type region 135. The concentration of P-type dopant species in P-type region 145 is less than a concentration of P-type dopant species in second N-type region 150. Although N-type region 130 is designated N++ and N-type region 135 is designated N+, alternatively they may be designated N+ and N− respectively. Although P-type region 145 is designated P+ and P-type region 150 is designated P++, alternatively they may be designated P− and P+ respectively.

In one example the concentration of N-type dopant in N-type region 130 is between about 10¹⁹ atm/cm³ and about 10²¹ atm/cm³ and the concentration of N-type dopant in N-type region 135 is between about 1¹⁷ atm/cm³ and about 10⁸ atm/cm³ with the understanding that the concentration of N-type dopant species in N-type region 130 is always greater than the concentration of N-type dopant species in N-type region 135.

In one example the concentration of P-type dopant in P-type region 145 is between about 10¹⁸ atm/cm³ and about 10¹⁹ atm/cm³ and the concentration of P-type dopant in P-type region 150 is between about 1¹⁹ atm/cm³ and about 10²¹ atm/cm³ with the understanding that the concentration of P-type dopant species in P-type region 145 is always less than the concentration of P-type dopant species in P-type region 150.

Formed adjacent to (or over, depending on the degree of out-diffusion of extension 136 of N-type region 135) N-type region 135 and over P-type region 145 is an electrically conductive gate 155 isolated from N-type region 135 and P-type region 145 by a gate dielectric 160. In one example gate dielectric 160 comprises silicon dioxide and is between about 500 and about 4000 microns thick. In one example, gate dielectric 165 is a dielectric of sufficient thickness to have a dielectric breakdown of over about 40 volts. A region of N-body 120 under gate 155 separates N-type region 135 from P-type region 145.

An N-type contact 165 is provided to isolation 115 and regions of dielectric shallow trench isolation (STI) 170 extend from the top surface of substrate 100, into the substrate further than any of first and second N-type regions 130 and 135 and first and second P-type regions 145 and 150, but not further than N-body 120. STI 170 extends laterally (along the surface of substrate 100) over isolation 115, N-tub 110 and N-body 120, but not over first and second N-type regions 130 and 135 and first and second P-type regions 145 and 150 or the region of N-body 120 between N-type region 135 and P-type region 145 under gate 155.

In ESD diode 105, first and second N-type regions 130 and 135 are physically and electrically connected by a metal silicide layer (shown as a heavy line) formed ion the top surfaces of the first and second N-type regions and are wired as the cathode of the diode. A metal silicide layer (shown as a heavy line) is formed on the top surface of gate 155 and a metal silicide layer (shown as a heavy line) is formed on the top surface of P-type region 150, which are both wired together to form the anode of the diode. A metal silicide a metal silicide layer (shown as a heavy line) is formed on the top surface of contact 165. A voltage may be applied to contact 165 to back bias isolation 115 as well as to allow modulation of N-tub 110, thus controlling the trigger current of the device.

FIG. 1B is a cross-sectional drawing the first ESD diode illustrating an alternative isolation scheme according to the embodiment of the present invention. In FIG. 1B, an ESD diode 105A is similar to ESD diode 105 of FIG. 1B, except that diffused isolation 115 (see FIG. 1A) is replaced by a dielectric deep trench (DT) 175. DT 175 extends from a top surface of substrate 100 into the substrate further than N-tub 110 extends into the substrate. DT 175 abuts the entire perimeter of N-tub 110. While all subsequent ESD trigger and voltage clamp devices will be illustrated using diffused isolation, it should be understood that DT isolation may be substituted.

Another feature common to all ESD trigger and voltage clamp devices according to embodiments of the present invention is the vertical stack of the cathode includes an N+ region in an N-body in an N-tub. The vertical direction is perpendicular to the top surface of substrate 100.

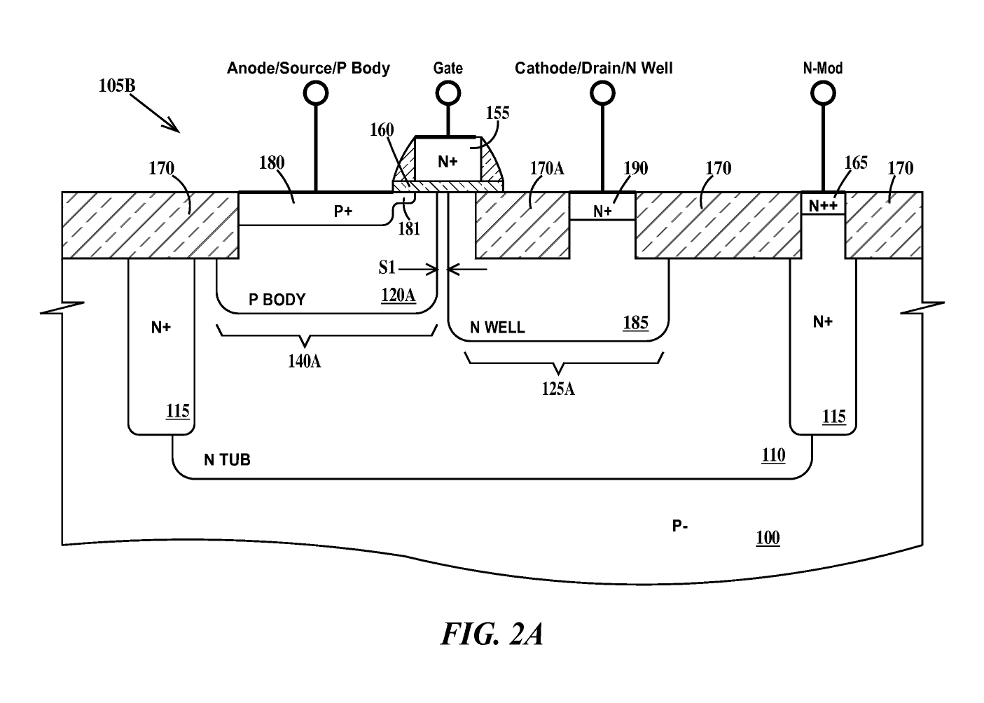

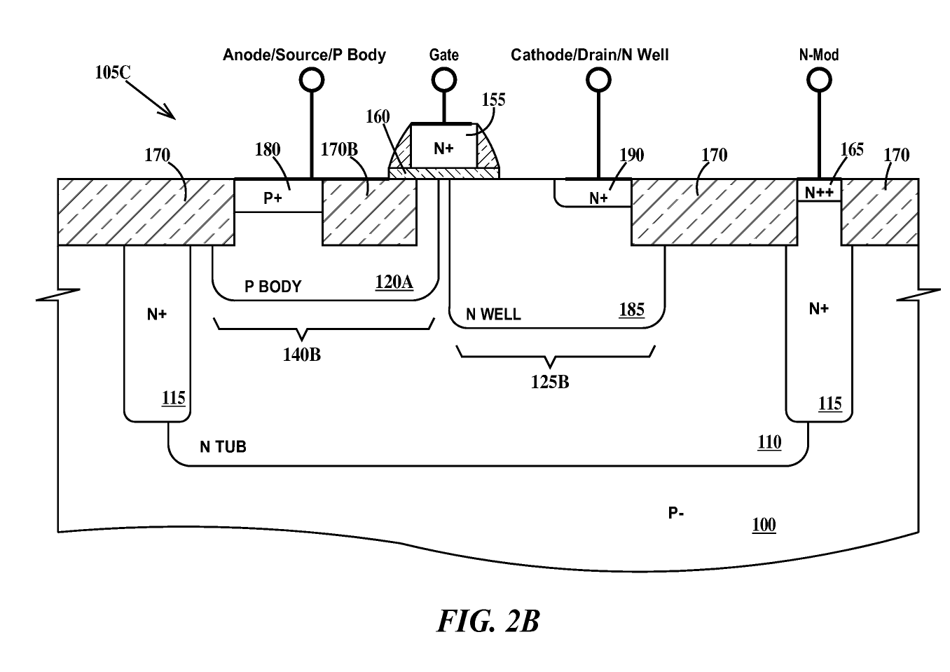

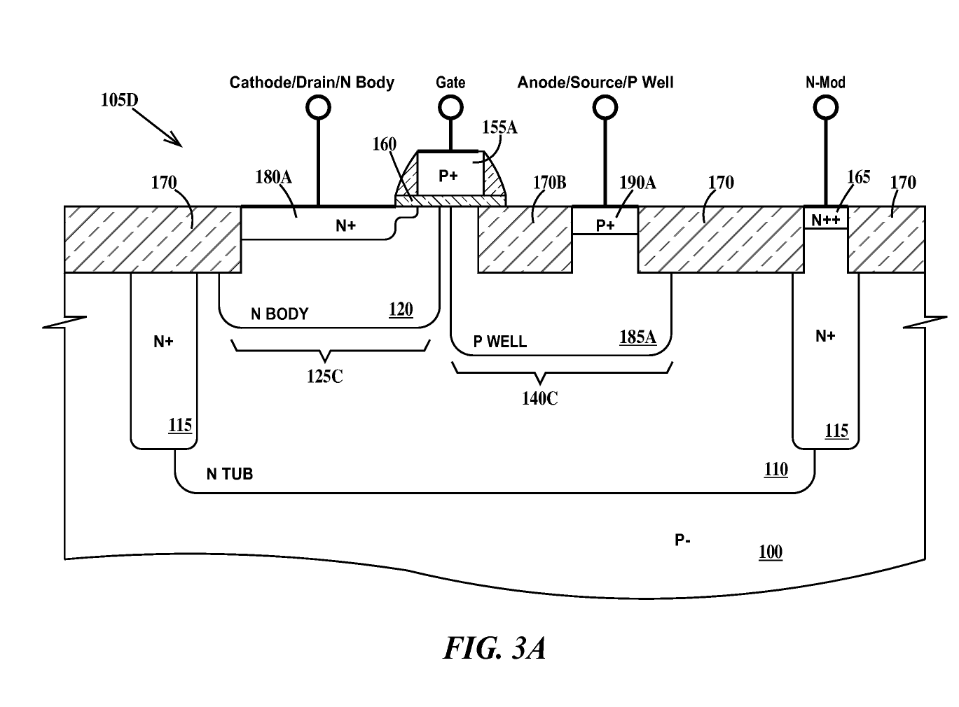

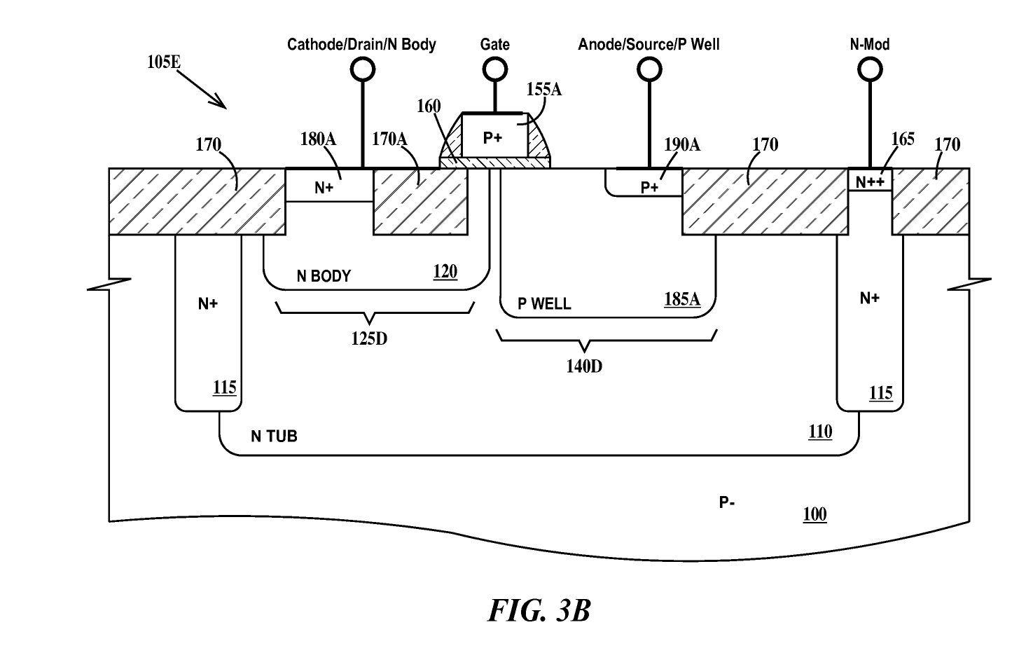

FIGS. 2A, 2B, 3A and 3B are cross-sectional drawings of third, fourth, fifth and sixth ESD diodes according to embodiments of the present invention. In FIG. 2A, an ESD diode 105B is similar to ESD diode 105 of FIG. 1A except first and second first P-type regions 145 and 150 are replaced by a single P-type region 180 formed in a P-body 120A formed in N-tub 120A and first and second N-type regions 130 and 135 are replaced with a single N-type region 190 and a region of STI 170A which is formed in an N-well 185. P-body 120A and N-well 185 extend under gate 155 and are separated by a region of N-tub 110 under gate 155. P-type region 180 extends under gate dielectric 160 (and may extend under gate 155 depending upon the out diffusion of extension region 181 of P-type region 180). P-body 120A extends under gate 155 further than P-type region 180. STI 170A extend under gate 155 and abuts N-type region 190.

A vertically graded anode 140A includes P-type region 180 and P-body 120A. A vertically graded cathode 125A includes N-type region 190 and N-well 185. Graded anode 140A is graded vertically instead of laterally as in graded anode 140 of FIG. 1A. Graded cathode 125A is graded vertically instead of laterally as in graded cathode 125 of FIG. 1A.

In one example the concentration of N-type dopant in N-type region 190 is between about 10¹⁹ atm/cm³ and about 10²¹ atm/cm³ and the concentration of N-type dopant in N-well 185 is between about 10¹⁶ atm/cm³ and about 10¹⁸ atm/cm³ with the understanding that the concentration of N-type dopant species in N-type region 190 is always greater than the concentration of N-type dopant species in N-well 185.

In one example the concentration of P-type dopant in P-type region 180 is between about 10¹⁹ atm/cm³ and about 10²¹ atm/cm³ and the concentration of P-type dopant in P-body 120A is between about 10¹⁷ atm/cm³ and about 10¹⁸ atm/cm³ with the understanding that the concentration of P-type dopant species in P-type region 180 is always greater than the concentration of P-type dopant species in P-body 120A.

P-body 120A and N-well 185 are spaced apart a distance S1 under gate 155. Space S1 may be pre-set during fabrication of device 105B inn order to center the designed breakdown current of the device, which can then be further controlled by bias voltage applied to contact 165. The extension of STI under gate 155 prevents electrical overstress of the device. P-type region 180 and gate 155 are wired together in ESD diode 105B.

In FIG. 2B, an ESD diode 105C is similar to ESD diode of FIG. 2A, except STI 170A (see FIG. 2A) is not present and an STI 170B is formed between P-type region 180 and gate 155 and STI 170B extends under gate 155. A vertically graded anode 140B includes P-type region 180 and P-body 120A. A vertically graded cathode 125B includes N-type region 190 and N-well 185. P-type region 180 and gate 155 are wired together in ESD diode 105C.

In FIG. 3A, and ESD diode 105D is similar to ESD diode 105B of FIG. 2A except P-body 120A is replaced with N-body 120, P-type region 180 is replaced with N-type region 180A, N-well 185 is replaced with a P-well 185A, N-type region 190 is replaced with a P-type region 190A and STI 170A is replaced with STI 170B. A vertically graded anode 140C includes P-type region 190A and P-well 185A. A vertically graded cathode 125C includes N-type region 180A and N-body 120A. ESD diode device, P-type region 190A and gate 155 are wired together.

In one example the concentration of N-type dopant in N-type region 180A is between about 10¹⁹ atm/cm³ and about 10²¹ atm/cm³ and the concentration of N-type dopant in N-body 120 is between about 10¹⁷ atm/cm³ and about 10¹⁸ atm/cm³ with the understanding that the concentration of N-type dopant species in N-type region 180A is always greater than the concentration of N-type dopant species in N-body 120.

In one example the concentration of P-type dopant in P-type region 190A is between about 10¹⁹ atm/cm³ and about 10²¹ atm/cm³ and the concentration of P-type dopant in P-well 185A is between about 10¹⁷ atm/cm³ and about 10¹⁸ atm/cm³ with the understanding that the concentration of P-type dopant species in P-type region 190A is always greater than the concentration of P-type dopant species in P-well 185A.

In FIG. 3B, and ESD diode 105E is similar to ESD diode 105C of FIG. 2B except P-body 120A is replaced with N-body 120, P-type region 180 is replaced with N-type region 180A, N-well 185 is replaced with P-well 185A, N-type region 190 is replaced with P-type region 190A and STI 170B is replaced with STI 170A. A vertically graded anode 140D includes P-type region 190A and P-well 185A. A vertically graded cathode 125C includes N-type region 180A and N-body 120A. P-type region 190A and gate 155 are wired together in ESD diode 105E.

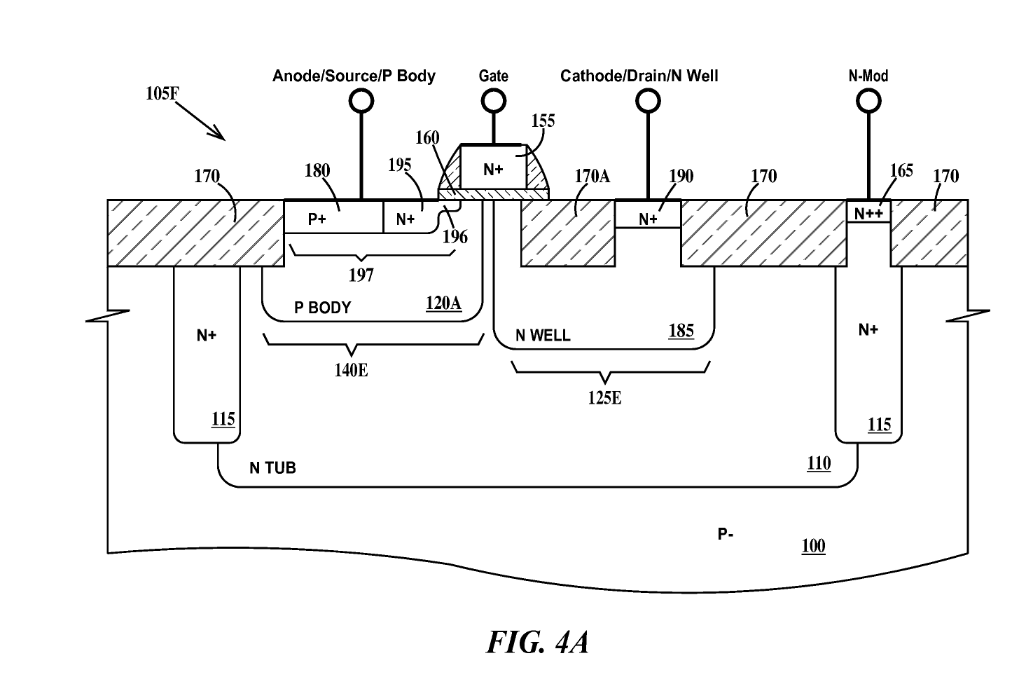

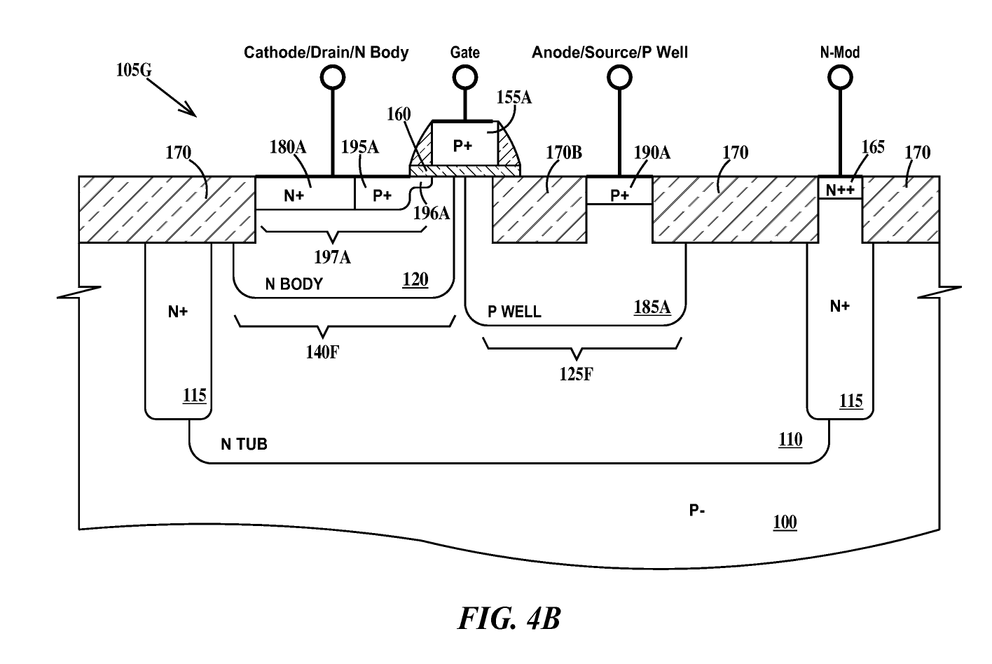

FIG. 4A is a cross-sectional drawing of a first ESD transistor according to an embodiment of the present invention. In FIG. 4A, an ESD transistor 105F is similar to ESD diode 105B of FIG. 2A, except an N-type region 195 is completely formed in P-body 120A between P-type region 180 and N-well 185. N-type region 195 extends under gate dielectric 160 (and may extend under gate 155 depending upon the out diffusion of extension region 196 of N-type region 195). P-type region 180 and N-type region 195 form an abutted contact 197 and are physically and electrically connected by a metal silicide layer (shown as a heavy line). A vertically graded anode 140E includes P-type region 180 and P-body 120A. A vertically graded cathode 125E includes N-type region 190 and N-well 185.

FIG. 4B is a cross-sectional drawing of a seventh ESD diode according to an embodiment of the present invention. In FIG. 4B and ESD diode 105G is similar to ESD transistor 105F of FIG. 4A except P type region 180 is replaced by N-type region 180A, N-type region 195 is replaced by P-type region 195A, P-body 120A is replaced by N-body 120, STI 170A is replaced by STI 170B, N-type region 190is replaced by P-type region 190A and N-well 185 is replaced by P-well 185A.

P-type region 195A extends under gate dielectric 160 (and may extend under gate 155 depending upon the out diffusion of extension region 196A of P-type region 195A). N-type region 180A and P-type region 195A form an abutted contact 197A and are physically and electrically connected by a metal silicide layer (shown as a heavy line). A vertically graded anode 140F includes P-type region 190A and P-well 185A. A vertically graded cathode 125F includes N-type region 180A and N-body 120A. P-type region 195A and gate 155 are wired together ESD diode 105G.

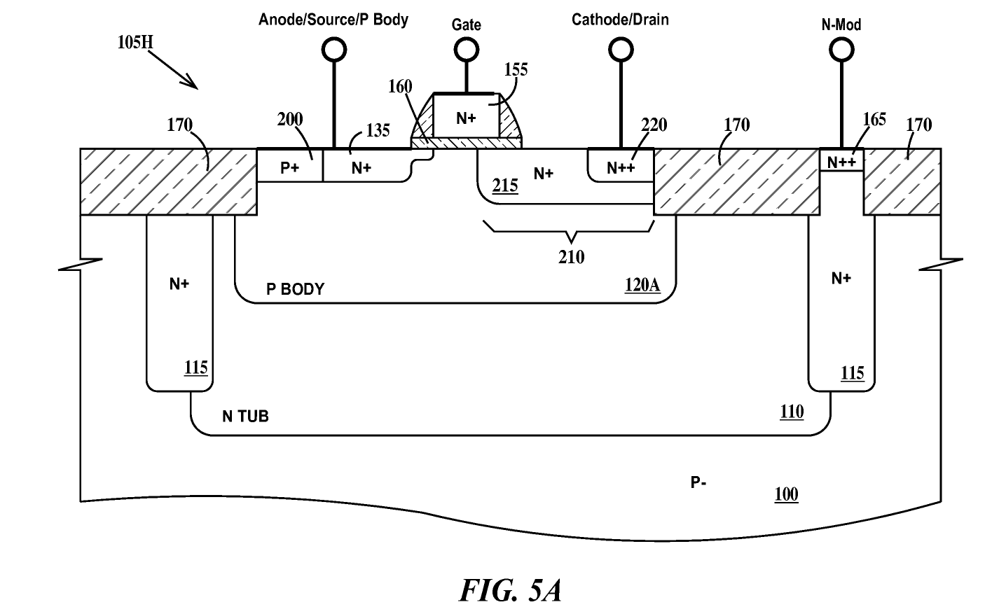

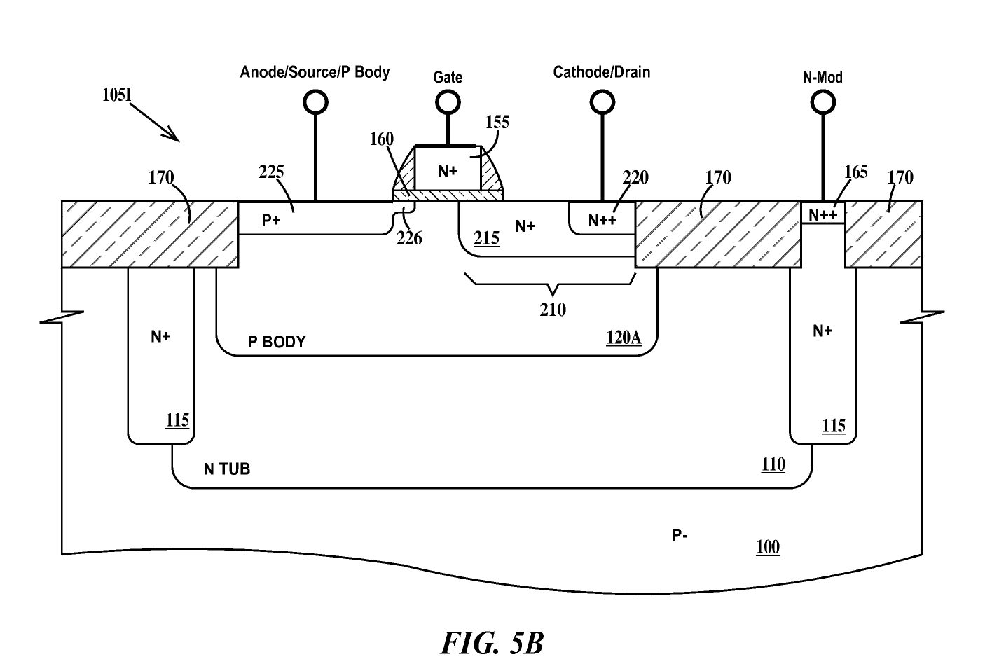

FIG. 5A is a cross-sectional drawing of a second ESD transistor according to an embodiment of the present invention. In FIG. 5, an ESD transistor 105H is similar to ESD diode 105 of FIG. 1A except N-type region 130 is replaced with P-type region 200, P-type region 145 is replaced by N-type region 215, P-type region 150 is replaced with B-type region 220 and N-body 120 is replaced with P-body 120A. P-type region 200 and N type region 135 form an abutted contact 205 and are physically and electrically connected by a metal silicide layer (shown as a heavy line). A laterally graded region 210 includes N-type region 215 and a N-type region 215.

In one example the concentration of N-type dopant in N-type region 215 is between about 10¹⁸ atm/cm³ and about 10¹⁹ atm/cm³ and the concentration of N-type dopant in N-type region 220 is between about 10¹⁹ atm/cm³ and about 10²¹ atm/cm³ with the understanding that the concentration of N-type dopant species in N-type region 220A is always greater than the concentration of N-type dopant species in N-type region 220.

FIG. 5B is a cross-sectional drawing of an eighth ESD diode according to an embodiment of the present invention. In FIG. 5B, an ESD diode 105 is similar to ESD transistor 105H of FIG. 5A except abutted contact 205 is replaced with a P-type region 225. P-type region 225 extends under gate dielectric 160 (and may extend under gate 155 depending upon the out diffusion of extension region 226 of P-type region 225).

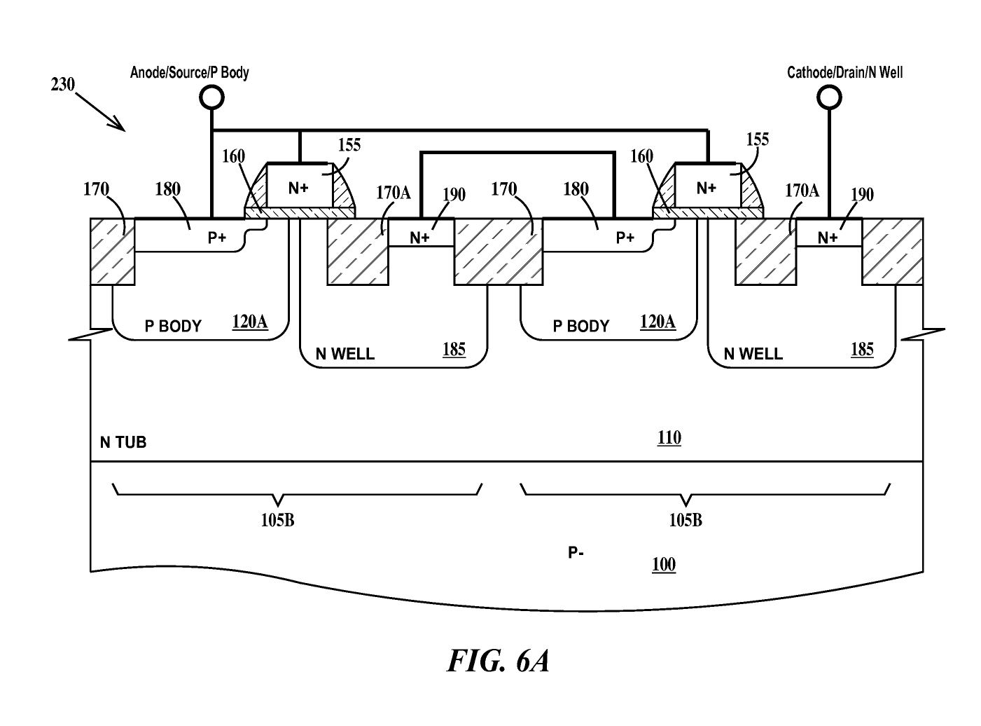

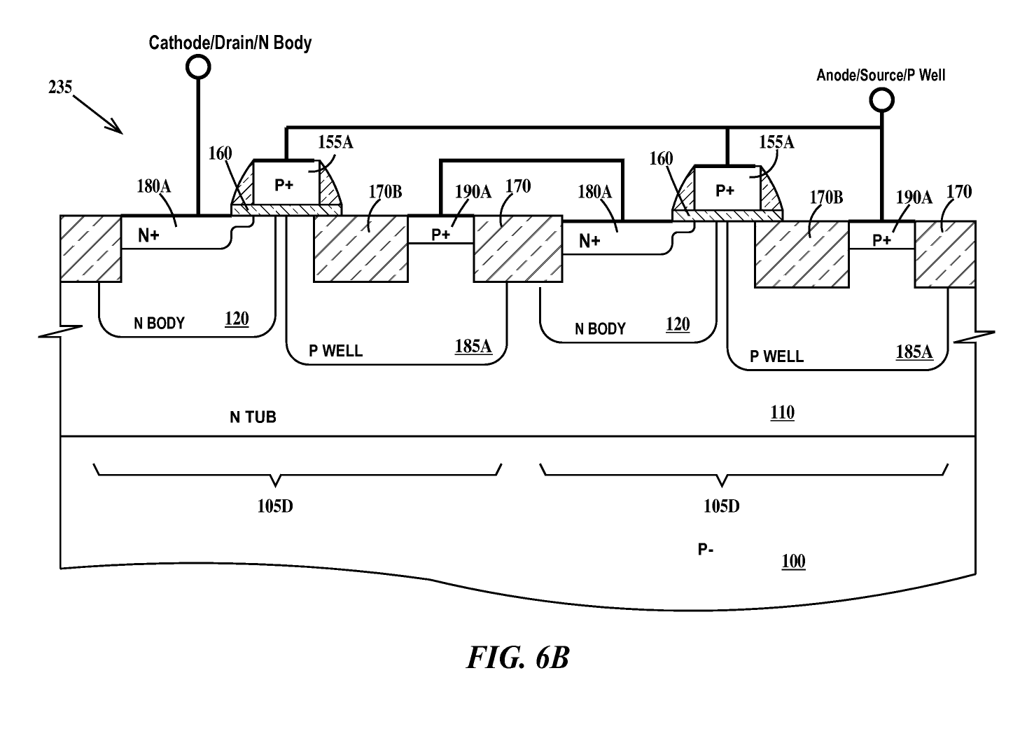

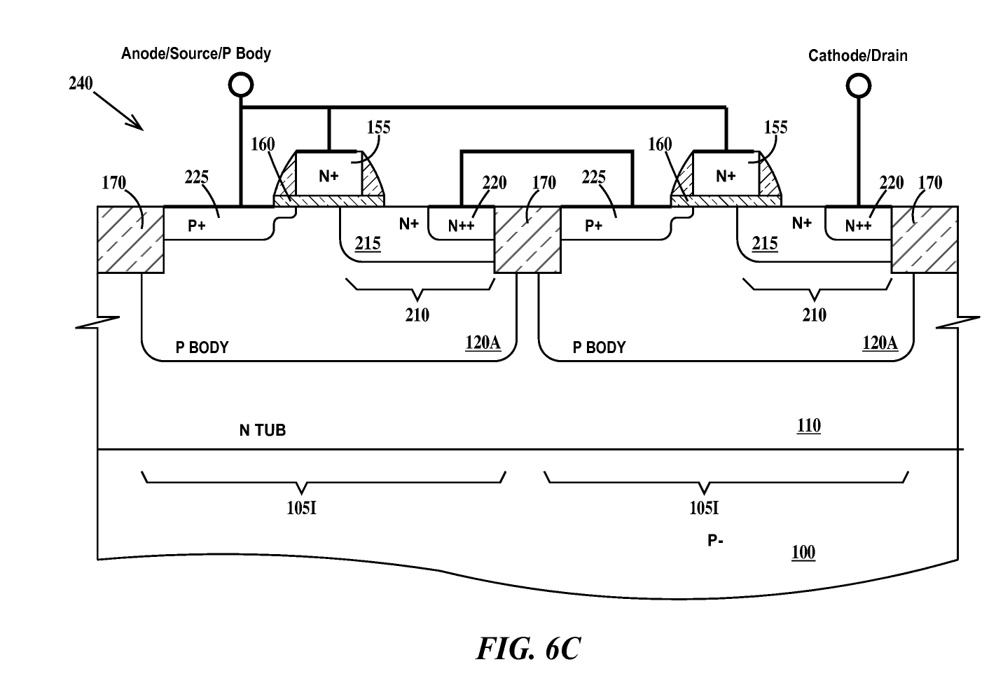

FIGS. 6A, 6B and 6C are exemplary gated diode ESD string protection devices according to embodiments of the present invention. In FIG. 6A, an ESD diode 230 includes two ESD diodes 105B wired as diodes in series and formed in the same N-tub 110. The N-tub contact (165 of FIG. 2B) is not illustrated in FIG. 6A, but is present. While only two ESD diodes 105B are illustrated in N-tub 110, two or more ESD diodes may be wired in series.

In FIG. 6B, an ESD diode 235 includes two ESD diodes 105D wired as diodes in series and formed in the same N-tub 110. The N-tub contact (165 of FIG. 3A) is not illustrated in FIG. 6B, but is present. While only two ESD diodes 105N are illustrated in N-tub 110, two or more ESD diodes may be wired in series.

In FIG. 6C, an ESD diode 240 includes two ESD diodes 105 T wired as diodes in series and formed in the same N-tub 110. The N-tub contact (165 of FIG. 5B) is not illustrated in FIG. 6C, but is present. While only two ESD diodes 105I are illustrated in N-tub 110, two or more ESD diodes may be wired in series.

Any of the ESD diodes described supra may be wired in series to form ESD diode strings.

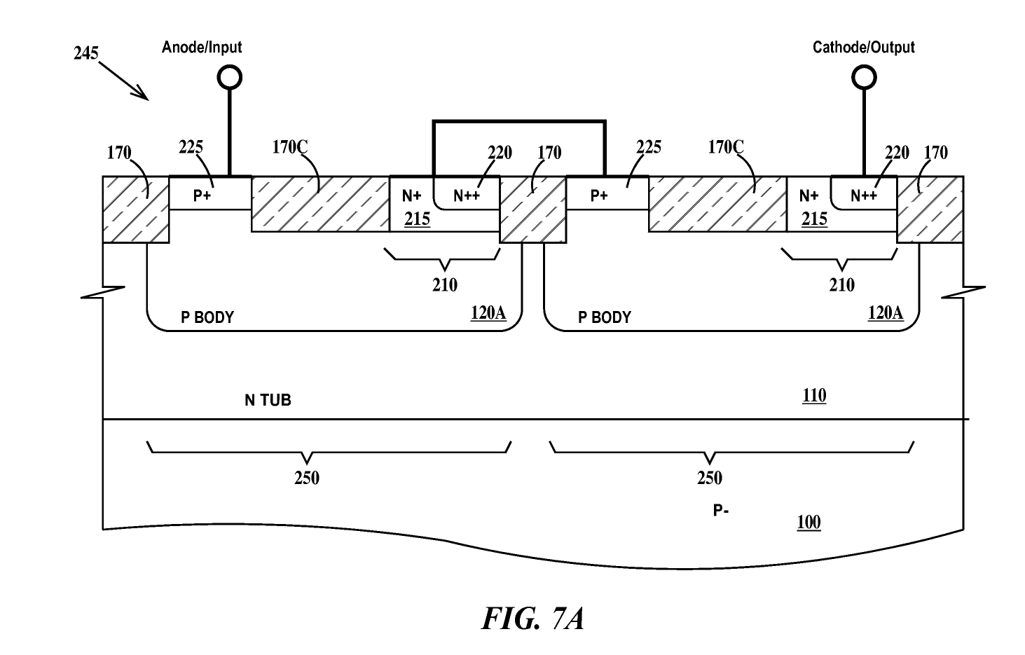

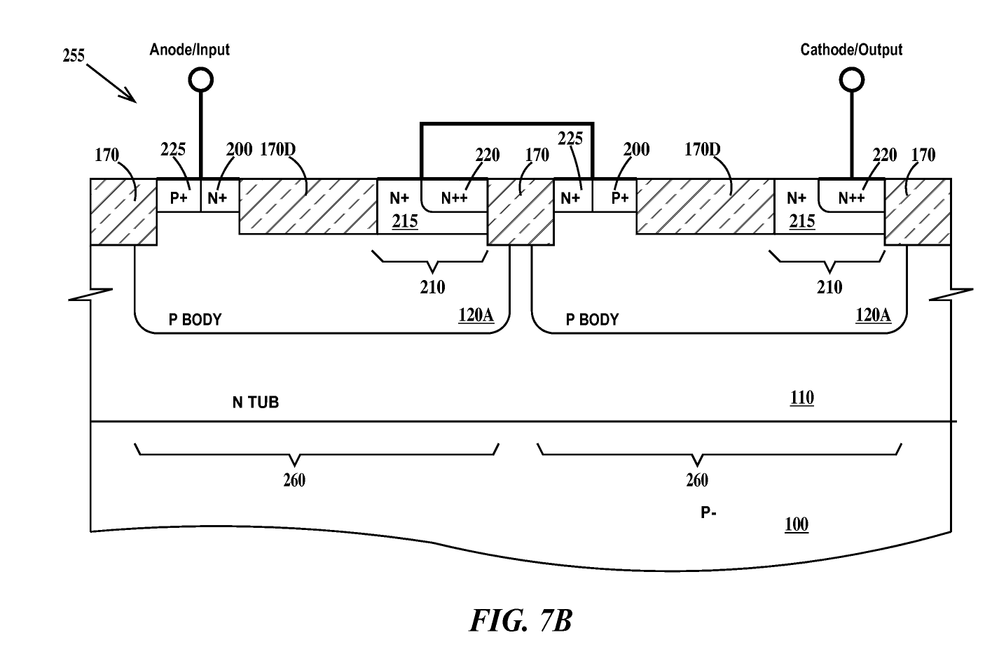

FIGS. 7A and 7B are exemplary diode ESD string protection devices according to embodiments of the present invention. In FIG. 7A, an ESD diode 245 includes two ESD diodes 250 wired in series and formed in the same N-tub 110. Each ESD diode 250 is essentially an ESD diode 105 of FIG. 5B without gate 155 and gate dielectric 160 and with a region of STI 170C abutting and separating P-type region 225 and N-type region 215. The N-tub contact (165 of FIG. 5B) is not illustrated in FIG. 7A, but is present. While only two ESD diodes 250 are illustrated in N-tub 110, two or more ESD diodes may be wired in series.

In FIG. 7B, an ESD diode 255 includes two ESD diodes 260 wired as diodes in series and formed in the same N-tub 110. Each trigger devices 260 is essentially an ESD device 105H of FIG. 5A without gate 155 and gate dielectric 160 and with a region of STI 170B abutting and separating N-type region 220 and N-type region 215. The N-tub contact (165 of FIG. 5B) is not illustrated in FIG. 7A, but is present. While only two ESD diodes 250 are illustrated in N-tub 110, two or more ESD diodes may be wired in series.

Any of the ESD diodes or transistor described supra may formed without gates and be wired in series to form ESD diode strings.

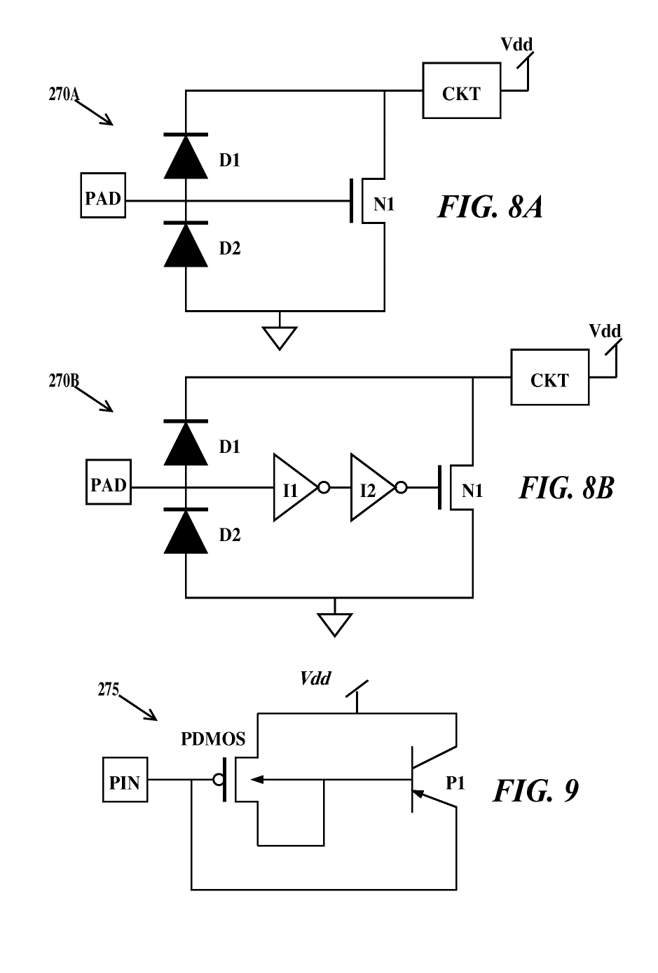

FIGS. 8A and 8B are ESD protection circuits according to embodiments of the present invention. In FIG. 8A, an ESD protection circuit 270A includes a first ESD trigger diode D1, a second and optional ESD trigger diode D2 and an ESD transistor N1. The cathode of diode D1 is connected to the circuit to protected and the drain of voltage clamp device N1. The source of voltage clamp device is connected to ground and to the anode of diode D2. The anode of diode D1 is connected to an I/O pad, the cathode of diode D2 and the gate of device N1.

Diodes D1 and D2 are advantageously and independently PDMOS devices selected from devices such as ESD diode 105/105A of FIG. 1A/1B, ESD diode 105B of FIG. 2A, ESD diode 105 of FIG. 1A, ESD diode 105C of FIG. 2B, ESD diode 105D of FIG. 3A, ESD diode 105E of FIG. 3B, ESD diode 105G of FIG. 4B, ESD diode 105I of FIG. 5B, ESD diode 230 of FIG. 6A, ESD diode 230 of FIG. 6A, ESD diode 235 of FIG. 6B, ESD diode 240 of FIG. 6C, ESD diode 245 of FIG. 7A and ESD diode 255 of FIG. 7B wired as diodes. Diode D2 may be replaced by a resistor

ESD transistor N1 is advantageously an NDMOS device selected from such devices as ESD transistor 105F of FIG. 4A and ESD transistor 105H of FIG. 5A.

FIG. 8B, an ESD protection circuit 270B is similar to ESD protection circuit 270A of FIG. 8A except for invertors I1 and I2 inserted between the anode of diode D1 and the gate of ESD transistor N1. Invertors I1 and I2 each include a thick gate dielectric PDMOS pull-up transistor and a thick gate dielectric NDMOS pull-down transistor, each rated for at least 40 volts. In one example, the PDMOS and NDMOS devices of inverters I1 and I2 are selected from devices 105 through 105I described supra and illustrated respectively in FIGS. 1A through 5B.

FIG. 9 is a control circuit for controlling PDMOS based ESD protection circuits. In FIG. 9, an N-tub bias control circuit 275 includes a PDMOS device wired as a diode (diode D1 and D2 of FIGS. 8A and 8B) and a PNP bipolar transistor P1. A control pin (PIN) is connected to the gate of the PDMOS device and the emitter of transistor P1. The source of the PDMOS device is connected to V_{dd} and the collector of transistor P1. The base of transistor P1 is connected to the drain of the PMOS device and to the N-tub of the PDMOS device (through contact 165, for example of FIG. 1A). Applying a bias voltage to PIN controls the overall voltage applied to the N-tub.

In one example, transistor P1 is a lateral bipolar transistor comprising a polysilicon edge defined P-type region bounded by STI on a first side of the gate, an N-well under the gate, an STI edge under the gate on a second and opposite side of the gate, a P-body under the STI edge and a P-type region in the P-body bounded by STI on all edges. The lateral PNP can be itself biased, float or the gate connection made through an HVPMOS (high voltage PMOS) device to avoid overstressing the lateral PNP.

Thus, the embodiments of the present invention provide ESD protection and devices and circuits that can provide ESD protection for integrated circuits operating at 20 volts and above.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A device, comprising:
an N-tub in a P-type substrate;
a graded anode comprising a first P-type region in a second P-type region and located within said N-tub, a concentration of P-type dopant in said first P-type region being greater than a concentration of P-type dopant in said second P-type region; and
a graded cathode comprising a first N-type region in a second N-type region and located within said N-tub, a concentration of N-type dopant in the first N-type region being greater than a concentration of N-type dopant in said second N-type region.

2. The device of claim 1, further including:
an N-body in said N-tub, said graded anode and said graded cathode both in said N-body within said N-tub.

3. The device of claim 1, wherein said second P-type region is a P-body in said N-tub, said graded cathode being in said P-body.

4. The device of claim 3, further including an N-type contact in said P-body, said N-type contact abutting said first P-type region.

5. The device of claim 1, wherein said second P-type region is a P-body in said N-tub and said second N-type region is an N-well in said N-tub.

6. The device of claim 5, further including an N-type contact in said P-body, said N-type contact abutting said first P-type region.

7. The device of claim 5, further including:
an electrically conductive gate and a gate dielectric overlapping said P-body and said N-well, a region of said N-tub between said P-body and said N-well under said gate; and
a region of dielectric in said N-well, abutting said first N-type region and extending under said gate.

8. The device of claim 5, further including:
an electrically conductive gate and a gate dielectric overlapping said P-body and said N-well, a region of said N-tub between said P-body and said N-well under said gate; and
a region of dielectric in said P-body, abutting said first P-type region and extending under said gate.

9. The device of claim 1, wherein said second N-type region is an N-body in said N-tub and said second P-type region is a P-well in said N-tub.

10. The device of claim 9, further including a P-type contact in said N-body, said P-type contact abutting said first P-type region.

11. The device of claim 9, further including:
an electrically conductive gate and a gate dielectric overlapping said N-body and said P-well, a region of said N-tub between said N-body and said P-well under said gate; and
a region of dielectric in said P-well, abutting said first P-type region and extending under said gate.

12. The device of claim 9, further including:
an electrically conductive gate and a gate dielectric overlapping said N-body and said P-well, a region of said N-tub between said N-body and said P-well under said gate; and
a region of dielectric in said N-body, abutting said first N-type region and extending under said gate.

13. A circuit, comprising:
a diode comprising:
a first N-tub in a P-type substrate;
a graded anode comprising a first P-type region in a second P-type region and located within said first N-tub, a concentration of P-type dopant in said first P-type region being greater than a concentration of P-type dopant in said second P-type region; and
a graded cathode comprising a first N-type region in a second N-type region and located within said first N-tub, a concentration of N-type dopant in the first N-type region being greater than a concentration of N-type dopant in said second N-type region;
a transistor comprising:
a second N-tub in a P-type substrate;
a third P-type region in a fourth P-type region and located within said second N-tub, a concentration of P-type dopant in said third P-type region being greater than a concentration of P-type dopant in said fourth P-type region;
a third N-type region in a fourth N-type region and located within said second N-tub, a concentration of N-type dopant in the third N-type region being greater than a concentration of N-type dopant in said fourth N-type region; and
an electrically conductive gate and a gate dielectric between said third P-type region and said third N-type region and over said second N-tub; and
wherein, said cathode of said diode is connected to a drain of said transistor, an anode of said diode is coupled to said gate of said transistor and coupled to ground, and a source of said transistor is connected to ground.

14. The circuit of claim 13, further including:
a resistor connected between said anode of said diode and ground.

15. The circuit of claim 13, further including:
an additional diode, a cathode of said additional diode connected to said anode of said diode and an anode of said additional diode connected to ground.

16. The circuit of claim 15, said additional diode comprising:
a third N-tub in said P-type substrate;
a graded anode comprising a fifth P-type region in a sixth P-type region and located within said third N-tub, a concentration of P-type dopant in said fifth P-type region being greater than a concentration of P-type dopant in said sixth P-type region; and
a graded cathode comprising a fifth N-type region in a sixth N-type region and located within said third N-tub, a concentration of N-type dopant in the fifth N-type region being greater than a concentration of N-type dopant in said sixth N-type region.

17. The circuit of claim 16, further including:
one or more circuits for applying a bias voltages to one or more of said first, second and third N-tubs.

18. The circuit of claim 13, further including:
a first inverter and a second inverter, a input of said first inverter connected to said anode of said diode, an output of said first inverter connected to an input of said second inverter, an output of said second inverter connected to said gate of said transistor.

19. The circuit of claim 18, wherein pull-up devices of said first and second inverters are P-type double-diffused metal-oxide-silicon (PDMOS) transistors and pull-down devices of said first and second inverters are N-type double-diffused metal-oxide-silicon (NDMOS) transistors.

20. The circuit of claim 13, wherein said diode is includes an electrically conductive gate and a gate dielectric between said third P-type region and said third N-type region and over said second N-tub, said gate of said diode electrically connected to said anode of said of said diode.
